(19) United States
(12) Patent Application Publication
(10) Pub. No.: US 2026/0100787 A1
(43) Pub. Date: Apr. 9, 2026

(54) PHASE DETECTING DEVICE AND METHOD OF DETECTING PHASE

(71) Applicant: Samsung Electronics Co., Ltd., Suwon-si (KR)

(72) Inventors: Jinook JUNG, Suwon-si (KR); Jaewoo PARK, Suwon-si (KR); Seungyeob BAEK, Suwon-si (KR); Myoungbo KWAK, Suwon-si (KR); Junghwan CHOI, Suwon-si (KR)

(73) Assignee: Samsung Electronics Co., Ltd., Suwon-si (KR)

(21) Appl. No.: 19/230,742

(22) Filed: Jun. 6, 2025

(30) Foreign Application Priority Data
Oct. 7, 2024 (KR) 10-2024-0136069

(51) Int. Cl. H04L 1/20; H03M 1/10

(52) U.S. Cl. CPC H04L 1/205; H03M 1/1023

(57) ABSTRACT

A phase detecting device according to some example embodiments includes: an analog front end for receiving a data signal and amplifying the data signal to generate an amplified signal; an analog-to-digital converter for sampling the amplified signal based on clock signals, and generating digital data signals; and a Mueller-Mueller phase detector for receiving the digital data signals from the analog-to-digital converter, and driving at least one operator from among operators based on transition between two continuously received digital data signals from among the digital data signals.

### CROSS-REFERENCE TO RELATED APPLICATION

This application claims priority to and the benefit of Korean Patent Application No. 10-2024-0136069 filed in the Korean Intellectual Property Office on Oct. 7, 2024, the entire contents of which are incorporated herein by reference.

### BACKGROUND

Some example embodiments relate to a phase detecting device and/or a phase detecting method for detecting a phase difference between data signals and clock signals.

Electronic devices operate internally through digital signal processing, but their interfaces with external devices primarily rely on analog signal transmission. As performance of the electronic devices improves, communication frequencies are becoming higher, and as the communication frequencies become higher, the impact of jitter in signals received from external devices may become more noticeable.

The effects of jitter may cause timing mismatch when a receiver samples an analog signal to convert to a digital one. Timing instability may cause bit errors and sampling distortion during the signal conversion process. Accordingly, the integrity of the analog signal received by the receiver from an external device may be damaged.

### SUMMARY

Some example embodiments attempt to provide a phase detecting device driven with low electric power, and/or a phase detecting method.

Alternatively or additionally, some example embodiments attempt to provide a phase detecting device and/or a phase detecting method for more precisely detecting a phase difference between data signals and clock signals.

According to some example embodiments, a phase detecting device includes an analog front end configured to receive a data signal and to amplify the data signal to generate an amplified signal; an analog-to-digital converter configured to sample the amplified signal based on clock signals, and to generate digital data signals; and a Mueller-Mueller phase detector configured to receive the digital data signals from the analog-to-digital converter, and to drive at least one operator from among operators based on a transition between at least two continuously received digital data signals from among the digital data signals.

Alternatively or additionally according to some example embodiments, a phase detecting device includes operators corresponding to transitions of two data sampling a multi-level signal at at least two adjacent sampling timings, and the operators configured to operate a sampling control signal for adjusting the sampling timing at which the signal is sampled; an operator selecting circuit configured to generate an operator selecting signal for selecting at least one of the operators; and at least one switch configured to transmit driving voltages to the operators from a voltage source based on the operator selecting signal.

Alternatively or additionally according to some example embodiments, a phase detecting method includes receiving at least two continuous digital data signals from a converter; determining phase information based on transition information of the at least two digital data signals; selecting an operator for receiving a phase determining signal based on the transition information; outputting the phase determining signal to the selected operator; and transmitting a switch control signal to the switch connected between the selected operator and the voltage source.

Alternatively or additionally according to some example embodiments, there is provided system comprising a memory controller configured to control a memory device, the memory controller including a transmitter configured to transmit digital data signals, and the memory device configured to receive the transmitted digital data signals, the memory device including a receiver. The receiver includes a Mueller-Mueller phase detector configured to receive the digital data signals, and to drive at least one operator from among a plurality of operators based on a transition between at least two continuously received digital data signals from among the digital data signals.

In some example embodiments, the receiver includes n analog-to-digital converters, where n is a power of two.

In some example embodiments, the system further includes a processor configured to obtain transition information, and to determine one of a phase delay or a phase lead of digital the digital data signals.

### BRIEF DESCRIPTION OF THE DRAWINGS

FIG. 1 shows a block diagram of a memory system according to some example embodiments.

FIG. 2 shows a block diagram on a memory device according to some example embodiments.

FIGS. 3 and 4 show block diagrams on a transmitter and a receiver included in a memory controller and a memory device according to some example embodiments.

FIG. 5 shows a block diagram of a receiver according to some example embodiments.

FIG. 6 shows a graph on a DQE signal according to some example embodiments.

FIG. 7 shows a circuit diagram on a TI ADC according to some example embodiments.

FIG. 8 shows a graph on a process for converting a DQE signal into digital data through an ADC.

FIG. 9 shows a block diagram on a configuration of a Mueller-Mueller phase detector according to some example embodiments.

FIG. 10 shows a flowchart on an operation of a phase determining decoder according to some example embodiments.

FIG. 11 shows a table on gains and current consumption generated by a Mueller-Mueller phase detector based on a transition of digital data.

FIG. 12 shows a block diagram on a computer device according to some example embodiments.

### DETAILED DESCRIPTION

In the following detailed description, only certain example embodiments have been shown and described, simply by way of illustration. As those of ordinary skill in the art would realize, the described example embodiments may be modified in various different ways, all without departing from the spirit or scope of the present invention.

Accordingly, the drawings and description are to be regarded as illustrative in nature and not restrictive, and like reference numerals designate like elements throughout the specification. In the flowcharts described with reference to the drawings in this specification, the operation order may be changed, various operations may be merged, certain operations may be divided, and certain operations may not be performed.

An expression recited in the singular may be construed as singular or plural unless the expression “one”, “single”, etc., is used. Terms including ordinal numbers such as first, second, and the like, will be used only to describe various components, and are not to be interpreted as limiting these components. The terms may only be used to differentiate one component from others.

Hereinafter, inventive concepts will be described in more detail through examples. The examples are merely for illustrating the present disclosure, and the scope of rights protection of the present disclosure is not limited by the examples.

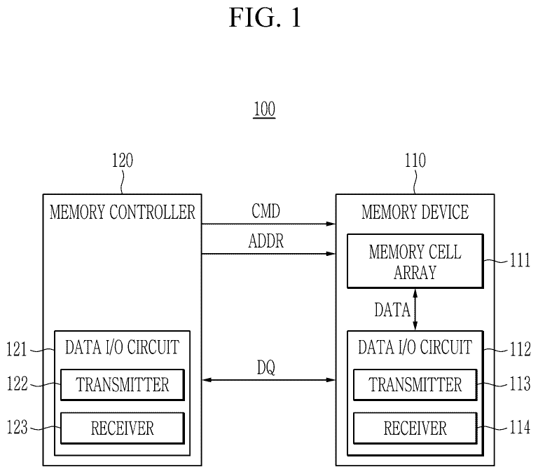

FIG. 1 shows a block diagram of a memory system according to some example embodiments.

Referring to FIG. 1, the memory system 100 includes a memory device 110 and a memory controller 120. In an embodiment, the memory device 110 and the memory controller 120 may be connected to each other through a memory interface and may transmit/receive signals to/from each other through the memory interface.

The memory device 110 includes a memory cell array 111 and a data input/output (I/O) circuit 112. The memory cell array 111 includes memory cells connected to rows and columns. In some example embodiments, the rows may be defined by word lines, and the columns may be defined by bit lines. The data I/O circuit 112 may store data transmitted from the outside in the memory cell array 111 and/or may output the data stored in the memory cell array 111 to the outside of the memory device 110 (i.e., the memory controller 120, etc.).

The data I/O circuit 112 may include a transmitter 113 and a receiver 114. The transmitter 113 may receive data DATA from the memory cell array 111 and may encode the data, and may output a data input/output signal DQ based on the encoded signal. In some example embodiments, a multi-symbol (or multi-level) modulation scheme may be used to modulate the signals communicated between the memory controller 120 and the memory device 110. Examples of the multi-symbol modulation scheme include one or more of the pulse amplitude modulation (PAM), the quadrature amplitude modulation (QAM), the quadrature phase shift keying (QPSK), and/or the like, but are not limited thereto. A multi-symbol signal may be modulated by using a modulation scheme including at least three levels to encode at least one bit of information. The multi-symbol modulation schemes and symbols may alternatively be referred to as non-binary, multi-bit, or higher-order modulation schemes and symbols. For example, the transmitter 113 may include an a-bit number of symbols depending on n-level pulse amplitude modulation (PAM-n) to generate and output the data input/output signal DQ that may express 2a (=n)-numbered data values. The transmitter 113 may generate and output the data input/output signal DQ for expressing four data values (00, 01, 10, and 11) including a 2-bit number of symbols depending on PAM-4. The data I/O circuit 112 will be assumed to use the PAM-4 scheme.

The receiver 114 may receive the data input/output signal DQ from the memory controller 120, may decode the received data input/output signal DQ, and may generate PAM-4 data. The PAM-4 data may include digital data expressing four data values (00, 01, 10, and 11). An operational process of the receiver 114 will be described below in detail.

The memory controller 120 provides a signal to the memory device 110 to control a memory operation of the memory device 110. The signal may include a command CMD and an address ADDR. In some example embodiments, the memory controller 120 may provide the command CMD and the address ADDR to the memory device 110 to access the memory cell array 111 and to control the memory operation such as read or write. The data may be transmitted as the data input/output signal DQ to the memory controller 120 from the memory cell array 111 according to a read operation, and the data may be transmitted as the data input/output signal DQ to the memory cell array 111 from the memory controller 120 according to a write operation.

The memory device 110 and the memory controller 120 may transmit/receive the data input/output signal DQ to/from each other by a serial interfacing scheme. The memory controller 120 may access the memory device 110 according to a request from a host (not shown) that is outside the memory system 100. The memory controller 120 may communicate with the host using various types of protocols. For example, the memory controller 120 may communicate with an external host by a parallel interfacing scheme. In some example embodiments, the memory controller 120 may communicate with the host by the serial interfacing scheme.

The command CMD may include one or more of an activate command, a read/write command, a refresh command, and a mode register write (MRW) command. The activate command may switch a target row of the memory cell array 111 into an active state to write data on the memory cell array 111 or read data from the memory cell array 111. The memory cell in the target row may be activated (e.g., driven) in response to the activate command. The read/write command may perform a read and/or write (e.g., program) operation on a target memory cell of the row that is switched to the active state. The refresh command may perform a refresh operation on the memory cell array 111. The MRW command may change a code stored in a mode register.

When the command CMD is a read command, the transmitter 113 may receive the data DATA from the memory cell array 111. The transmitter 113 may encode the data DATA based on the PAM-4, and may output the encoded signal as the data input/output signal DQ.

The data I/O circuit 121 of the memory controller 120 may output the data to the memory device 110 as the data input/output signal DQ or may receive the data input/output signal DQ from the memory device 110. The data I/O circuit 121 may include a transmitter 122 and a receiver 123. The transmitter 122 may transmit the data provided by the external host to the memory device 110. The transmitter 122 and the receiver 123 of the memory controller 120 are substantially the same as the transmitter 113 and the receiver 114 of the memory device 110 so the above-provided description on the transmitter 113 and the receiver 114 of the memory device 110 will be referred.

The memory device 110 may be or may include (or be included in) a storage device based on a semiconductor device. In some example embodiments, the memory device 110 may include a dynamic random access memory (DRAM) device. In some example embodiments, the memory device 110 may alternatively or additionally include another volatile and/or non-volatile memory device using the transmitter 113 or the receiver 114.

Elements described with reference to FIG. 1 may communicate with each other through a bus, such as a wired bus and/or a wireless bus, to send and/or receive information. The information may be or include but is not limited to data and/or commands, and may be encoded in various formats such as but not limited to analog and/or digital formats. The communication may be one-way and/or two-way and/or multiple way, e.g., in a broadcast manner. The information may be sent and/or received in a serial manner, and/or a parallel manner; example embodiments are not limited thereto.

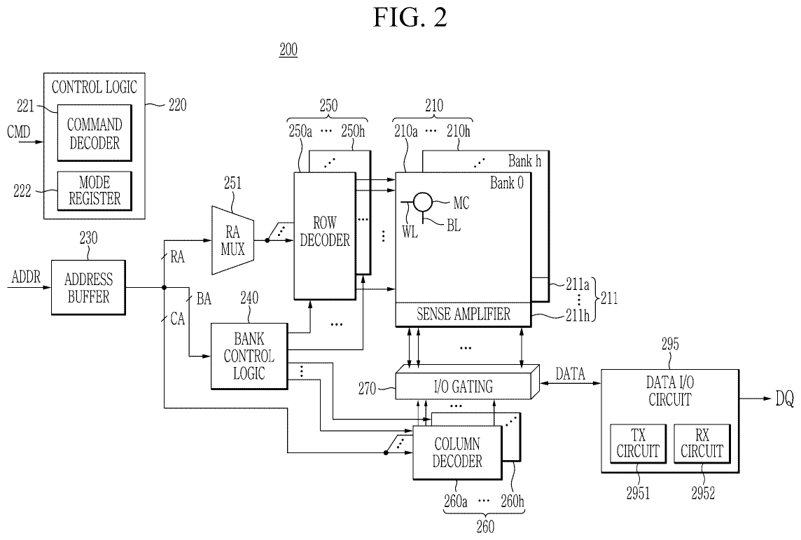

FIG. 2 shows a block diagram on a memory device according to some example embodiments.

Referring to FIG. 2, the memory device 200 includes a memory cell array 210, a sense amplifier 211, a control logic circuit 220, an address buffer 230, a row decoder 250, a column decoder 260, an input/output (I/O) gating circuit 270, and a data input/output (I/O) circuit 295.

The memory cell array 210 includes memory cells MC. In some example embodiments, the memory cell array 210 may include memory banks 210a to 210h. FIG. 2 shows eight memory banks BANK0 to BANKh 210a to 210h, and the number of the memory banks is not limited thereto. The respective memory banks 210a to 210h may include rows, columns, and memory cells MC arranged at crossing points of the rows and the columns. In some example embodiments, the rows may be defined by word lines WL, and the columns may be defined by bit lines BL. In some example embodiments, there may be or may include redundant and/or dummy memory cells included in at least one of the banks BANK0 to BANKh; example embodiments are not limited thereto.

The control logic circuit 220 controls all of or at least some of the operation of the memory device 200. For example, the control logic circuit 220 may generate control signals so that the memory device 200 may perform a read operation, a write operation, and an offset calibration operation. In some example embodiments, the control logic circuit 220 may include a command decoder 221. The command decoder 221 may generate control signals by decoding the command CMD received from the memory controller (e.g., 120 of FIG. 1).

In some example embodiments, the control logic circuit 220 may include a mode register 222 for setting an operation mode of the memory device 200. The mode register 222 may store codes for selecting an operator to be activated from among operators included in the transmitter 2951 and the receiver 2952. The codes may be expressed in a digital data form, e.g., in a vector form. The mode register 222 may receive a MRW signal from the memory controller 120, and may change the stored codes based on the MRW signal. Although not shown, the transmitter 2951 and the receiver 2952 may be integrated as a transceiver; example embodiments are not limited thereto.

The address buffer 230 may receive an address ADDR from the memory controller 120. The address ADDR includes row addresses RA indicating rows of the memory cell array 210 and column addresses CA indicating columns of the memory cell array 210. The row addresses RA are provided to the row decoder 250, and the column addresses CA are provided to the column decoder 260. In some example embodiments, the memory device 200 may further include a row address multiplexer 251. The row addresses RA may be provided to the row decoder 250 through the row address multiplexer 251. In some example embodiments, the address ADDR may further include a bank address BA indicating the memory bank. The bank address BA may be provided to the bank control logic 240.

In some example embodiments, the memory device 200 may further include a bank control logic 240 for generating bank control signals in response to the bank address BA. The bank control logic 240 may activate a row decoder 250 corresponding to the bank address BA from among the row decoders 250 and may activate a column decoder 260 corresponding to the bank address BA from among the column decoders 260 in response to the bank control signal.

The row decoder 250 selects the row to be activated from among the rows of the memory cell array 210 based on the row address. To this end, the row decoder 250 may apply a driving voltage to the word line corresponding to the row to be activated. In some example embodiments, the row decoders 250a to 250h corresponding to the memory banks 210a to 210h may be provided.

The column decoder 260 selects the column to be activated from among the columns of the memory cell array 210 based on the column address. For this purpose, the column decoder 260 may activate the sense amplifier 211 corresponding to the column address CA through the I/O gating circuit 270. In some example embodiments, the column decoders 260a to 260h corresponding to the memory banks 210a to 210h may be provided. In some example embodiments, the I/O gating circuit 270 may gate input/output data, and may include a data latch (not shown) for storing the data read from the memory cell array 210 and a write driver (not shown) for writing the data on the memory cell array 210. The data read from the memory cell array 210 may be sensed by the sense amplifier 211 and may be stored in the I/O gating circuit 270 (e.g., a data latch). In some example embodiments, the sense amplifiers 211a to 211h corresponding to the memory banks 210a to 210h may be provided.

In some example embodiments, the data (e.g., data stored in the data latch) read from the memory cell array 210 may be provided to the memory controller 120 through the data I/O circuit 295. The data to be written on the memory cell array 210 may be provided to the data I/O circuit 295 from the memory controller 120, and the data provided to the data I/O circuit 295 may be provided to the I/O gating circuit 270.

The data I/O circuit 295 may receive may output the data input/output signal DQ or may receive the data input/output signal DQ. The data I/O circuit 295 may include a TX circuit (or a transmitter) 2951 and an RX circuit (or a receiver) 2952. The transmitter 2951 may encode the data DATA transmitted from the I/O gating circuit 270 based on PAM-4, and may output a resultant signal as the data input/output signal DQ. The receiver 2952 may decode the received data input/output signal DQ to restore a resultant signal as a PAM-4 signal, and may transmit data DATA based on the restored signal to the I/O gating circuit 270.

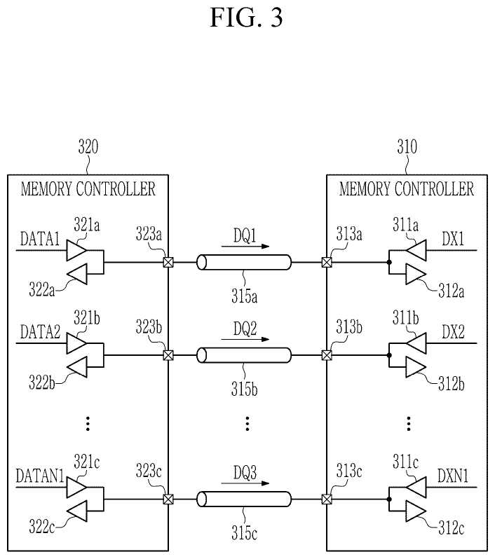

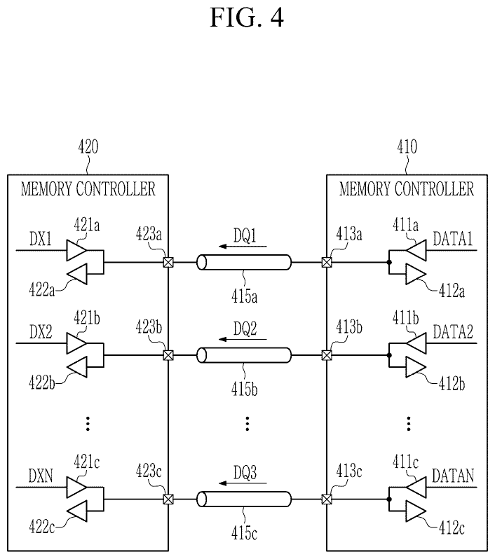

FIG. 3 and FIG. 4 show block diagrams on a transmitter and a receiver included in a memory controller and a memory device according to some example embodiments.

Referring to FIG. 3 and FIG. 4, the memory system 100 of FIG. 1 includes a semiconductor memory device 310, a memory controller 320, and channels 315a, 315b, and 315c.

The semiconductor memory device 310 may include transmitters 311a, 311b, and 311c, receivers 312a, 312b, and 312c, and data input/output pads 313a, 313b, and 313c. The memory controller 320 may include transmitters 321a, 321b, and 321c, receivers 322a, 322b, and 322c, and data input/output pads 323a, 323b, and 323c. Example embodiments illustrate that the transmitters 311a, 311b, and 311c are in correspondence with receivers 312a, 312b, and 312c; similarly, transmitters 321a, 321b, and 321c are shown to be in correspondence with receivers 322a, 322b, and 322c. However, example embodiments are not necessarily limited thereto. The number of transmitters may be the same as, or different from (e.g., greater than or less than) the number of receivers; example embodiments are not limited thereto.

The respective transmitters 311a, 311b, 311c, 321a, 321b, and 321c may generate multi-level signals. The respective receivers 312a, 312b, 312c, 322a, 322b, and 322c may receive the multi-level signals. The transmitters 311a, 311b, 311c, 321a, 321b, and 321c and the receivers 312a, 312b, 312c, 322a, 322b, and 322c may transmit multi-level data signals through the channels 315a, 315b, and 315c.

The respective data input/output pads 313a, 313b, 313c, 323a, 323b, and 323c may be connected to one of the transmitters 311a, 311b, 311c, 321a, 321b, and 321c and one of the receivers 312a, 312b, 312c, 322a, 322b, and 322c.

The channels 315a, 315b, and 315c may connect the memory controller 320 and the semiconductor memory device 310. The respective channels 315a, 315b, and 315c may be connected to one of (e.g., only one of) the transmitters 321a, 321b, and 321c and one of (e.g., only one of) the receivers 322a, 322b, and 322c through one of the data input/output pads 323a, 323b, and 323c, and may be connected to one of the transmitters 311a, 311b, and 311c and one of the receivers 312a, 312b, and 312c through one of the data input/output pads 313a, 313b, and 313c. The multi-level signals may be transmitted through the respective channels 315a, 315b, and 315c.

FIG. 3 shows an operation for transmitting data to the semiconductor memory device 310 from the memory controller 320. For example, the transmitter 321a may generate an output data signal DQ1 that is the multi-level signal based on input data DATA1, the output data signal DQ1 may be transmitted to the semiconductor memory device 310 from the memory controller 320 through the channel 315a, and the receiver 312a may receive the output data signal DQ1 and may obtain target data DX1 corresponding to the input data DATA1.

Similar to this, the transmitter 321b may generate an output data signal DQ2 that is the multi-level signal based on input data DATA2, the output data signal DQ2 may be transmitted to the semiconductor memory device 310 through the channel 315b, and the receiver 312b may receive the output data signal DQ2 and may obtain target data DX2 corresponding to the input data DATA2.

The transmitter 321c may generate an output data signal DQN1 that is the multi-level signal based on input data DATAN1, the output data signal DQN1 may be transmitted to the semiconductor memory device 310 through the channel 315c, and the receiver 312c may receive an output data signal DQ3 and may obtain target data DXN1 corresponding to the input data DATAN1.

FIG. 4 shows an operation for transmitting data to the memory controller 420 from the semiconductor memory device 410. The transmitter 411a may generate an output data signal DQ1 that is the multi-level signal based on the input data DATA1, the output data signal DQ1 may be transmitted to the memory controller 420 from the semiconductor memory device 410 through a channel 415a, and a receiver 422a may receive the output data signal DQ1 and may obtain target data DX1 corresponding to the input data DATA1.

Similar to this, the transmitter 411b may generate an output data signal DQ2 that is the multi-level signal based on the input data DATA2, the output data signal DQ2 may be transmitted to the memory controller 420 through a channel 415b, and a receiver 422b may receive the output data signal DQ2 and may obtain target data DX2 corresponding to the input data DATA2. The transmitter 411c may generate an output data signal DQN that is the multi-level signal based on the input data DATAN, the output data signal DQN may be transmitted to the memory controller 420 through a channel 415c, and the receiver 422c may receive the output data signal DQN and may obtain data DXN corresponding to the input data DATAN. For example, the input data DATA1, DATA2, and DATAN may be read data that are read from the semiconductor memory device 410.

For better understanding and ease of description, an operation of the receivers 312a, 312b, and 312c of the semiconductor memory device 310 when transmitting data to the semiconductor memory device 310 from the memory controller 320.

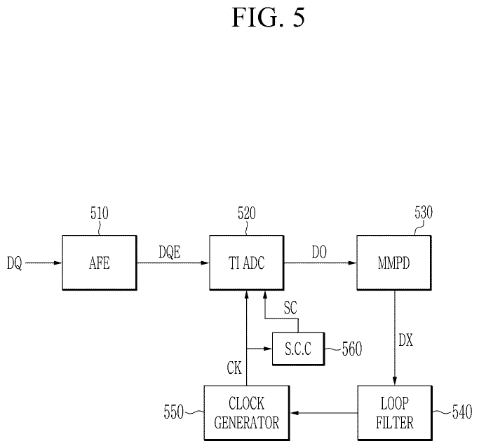

FIG. 5 shows a block diagram of a receiver according to some example embodiments.

The receivers 312a, 312b, and 312c of FIG. 3 of the semiconductor memory device 310 of FIG. 3 may receive the DQ signals from the transmitters 321a, 321b, and 321c of FIG. 3 of the memory controller 320 of FIG. 3. For better understanding and ease of description, the receivers 312a, 312b, and 312c of the semiconductor memory device 310 will now be described, which may be equivalently applied to the receivers 422a, 422b, and 422c of the memory controller 420 Referring to FIG. 5, the receivers 312a, 312b, and 312c may include an analog front end (AFE) 510, a time interleaved analog-to-digital converter (TI ADC) 520, a Mueller-Mueller phase detector (MMPD) 530, a loop filter 540, a clock signal generator 550, and a switch control signal generator (SSC) 560.

The analog front end 510 may amplify an original signal (hereinafter, DQ) received from the transmitters 321a, 321b, and 321c and may generate a processing signal (hereinafter, DQE). The time interleaved analog-to-digital converter (TI ADC) 520 may sample the DQE signals based on the clock signals CK received from the clock signal generator 550, and may convert them into digital data signals (DO). The Mueller-Mueller phase detector 530 may detect a phase from the digital data signals (DO). The loop filter 540 (e.g., a digital loop filter) may integrate outputs of the Mueller-Mueller phase detector 530. The clock signal generator 550 may adjust a frequency and a phase and may generate clock signals CK in response to the outputs of the loop filter. The switch control signal generator 560 may receive the clock signals CK from the clock signal generator 550, and may generate a switch control signal SC based on the clock signals CK. An operation of internal components of the receiver will now be described in detail.

The analog front end 510 is or includes (or is included in) a circuit disposed on an input end of the receiver to process the analog signal and convert the same into a digital signal. The analog front end 510 may amplify the fine analog signal to improve the same to satisfy a level that is appropriate for a digital signal. The analog front end 510 may remove or at least partially remove noise or an undesired frequency component included in the analog signal through filtering. The analog front end 510 may keep the necessary or expected frequency bandwidth using a low pass filter or a band pass filter and may refine the analog signal before undergoing a digital signal processing.

For example, the analog front end 510 may receive the DQ signal from the transmitter 321a, may amplify the DQ signal, and may improve the same to a level that is appropriate for a digital signal. The analog front end 510 may remove or at least partially remove noise or an undesired frequency component included in the DQ signal using a low pass filter. The analog front end 510 may amplify the DQ signal and remove noise to generate the DQE signal.

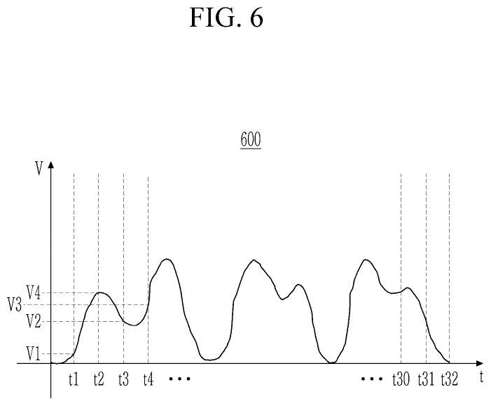

FIG. 6 shows a graph on a DQE signal according to some example embodiments.

Referring to FIG. 6, a voltage (V) of the DQE signal is variable with respect to time (t) during sections of t1 to t32. For example, the voltage (V) of the DQE signal may increase to V1 (V) from 0 (V) during the section of 0 to t1. The voltage (V) of the DQE signal may increase to V4 (V) from V1 (V) during the section of t1 to t2. The voltage (V) of the DQE signal may reduce to V2 (V) from V4 (V) during the section of t2 to t3. The voltage (V) of the DQE signal may increase to V3 (V) from V2 (V) during the section of t3 to t4.

Referring back to FIG. 5, the analog-to-digital converters ADC for converting fast analog signals into digital ones may be arranged in parallel with each other in the time interleaved analog-to-digital converter TI ADC 520. The respective analog-to-digital converters ADC may sample the input analog signal at specific time intervals and may generate digital signals. When a single analog-to-digital converter ADC is used, one input analog signal may be sequentially sampled, and when multiple analog-to-digital converters ADC are used, one input analog signal may be simultaneously sampled at specific time intervals. Hence, as the number of the analog-to-digital converters ADC increases, a sampling rate of the input analog signal may be increased.

For example, the time interleaved analog-to-digital converter (TI ADC) 520 may include a number of analog-to-digital converters, such as thirty-two analog-to-digital converters ADC. The number of analog-to-digital converters included in the TI-ADC 520 may be a power of two; example embodiments are not limited thereto. The time interleaved analog-to-digital converter (TI ADC) 520 may receive the DQE signal from the analog front end 510, and may sample the DQE signal at the thirty-two different time intervals to generate a digital signal.

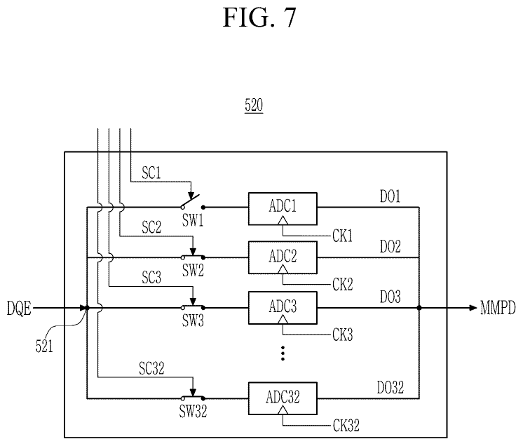

FIG. 7 shows a circuit diagram on a TI ADC according to some example embodiments.

The time interleaved analog-to-digital converter (TI ADC) 520 of FIG. 5 may include a number of analog-to-digital converters, such as thirty-two analog-to-digital converters ADC (ADC1, ADC2, ADC3, . . . , and ADC32), and the respective analog-to-digital converters ADC (ADC1, ADC2, ADC3, . . . , and ADC32) may sample the DQE signal 600 of FIG. 6 at thirty-two different time intervals using switches SW1, SW2, SW3, . . . , and SW32. The switches SW1, SW2, SW3, . . . , and SW32 may be connected between an input end 521 to which the DQE signal 600 is input and the analog-to-digital converters ADC (ADC1, ADC2, ADC3, . . . , and ADC32). The respective switches SW1, SW2, SW3, . . . , and SW32 may receive switch control signals SC1, SC2, SC3, . . . , and SC32 from the switch control signal generator 560 of FIG. 5, and may be turned on (or closed) or turned off (or opened) based on the switch control signals SC1, SC2, SC3, . . . , and SC32.

The switches SW1, SW2, SW3, . . . , and SW32 may be sequentially turned on at thirty-two different timings. For example, the first switch SW1 may be turned on during the section of t0 to t1, and the second switch SW2 may be turned on during the section of t1 to t2. In a like way, the third switch SW3 may be turned on during the section of t2 to t3, and the thirty-second switch SW32 may be turned on during the section of t31 to t32.

The DQE signal may be transmitted to the first analog-to-digital converter ADC1 through the activated first switch SW1 during the section of 0 to t1. The first analog-to-digital converter ADC1 may sample the DQE signal and may convert the same into first digital data DO1 at a rising edge of the first clock signal CK1. The DQE signal may be transmitted to the second analog-to-digital converter ADC2 through the activated second switch SW2 during the section of t1 to t2. The second analog-to-digital converter ADC2 may sample the DQE signal and may convert the same into second digital data DO2 at the rising edge of the second clock signal CK2. The DQE signal may be transmitted to the third analog-to-digital converter ADC3 through the activated third switch SW3 during the section of t2 to t3. The third analog-to-digital converter ADC3 may sample the DQE signal and may convert the same into third digital data DO3 at the rising edge of the third clock signal CK3. In a like way, the DQE signal may be transmitted to the thirty-second analog-to-digital converter ADC32 through the activated thirty-second switch SW32 during the section of t31 to t32. The thirty-second analog-to-digital converter ADC32 may sample the DQE signal and may convert the same into thirty-second digital data DO32 at the rising edge of the thirty-second clock signal CK32. The time interleaved analog-to-digital converter (TI ADC) 520 may receive the first clock to thirty-second clock signals CK1 to CK32 from the clock signal generator 550 of FIG. 5. The first digital data to the thirty-second digital data DO1 to DO32 converted by the analog-to-digital converters ADC1, ADC2, ADC3, . . . , and ADC32 may be transmitted to the Mueller-Mueller phase detector 530 of FIG. 5.

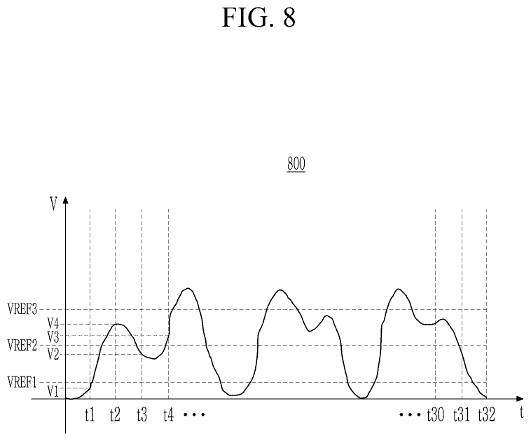

FIG. 8 shows a graph on a process for converting a DQE signal into digital data through an ADC.

The analog-to-digital converters ADC1, ADC2, ADC3, . . . , and ADC32 of FIG. 7 may convert the DQE signal into a digital data signal DO based on a first reference voltage VREF1, a second reference voltage VREF2, and a third reference voltage VREF3. In some example embodiments, the second reference voltage VREF2 may be twice the first reference voltage VREF1, and/or the third reference voltage VREF3 may be three times the first reference voltage VREF2; however, example embodiments are not limited thereto. For example, when the voltage of the DQE signal is less than the first reference voltage VREF1, the DQE signal may be converted into 00(2) that is the digital data signal DO. When the voltage of the DQE signal is equal to or greater than the first reference voltage VREF1 and less than the second reference voltage VREF2, the DQE signal may be converted into 01(2) that is the digital data signal DO. When the voltage of the DQE signal is equal to or greater than the second reference voltage VREF2 and less than the third reference voltage VREF3, the DQE signal may be converted into 10(2) that is the digital data signal DO. When the voltage of the DQE signal is equal to or greater than the third reference voltage VREF3, the DQE signal may be converted into 11(2) that is the digital data signal DO.

For example, the voltage V1 of the DQE signal at t1 is less than the first reference voltage VREF1 so the DQE signal may be converted into 00(2) that is the digital data signal DO during the section of 0 to t1. The voltage V4 of the DQE signal at t2 is equal to or greater than the second reference voltage VREF2 and less than the third reference voltage VREF3 so the DQE signal may be converted into 10(2) that is the digital data signal DO during the section of t1 to t2. The voltage V2 of the DQE signal at t3 is equal to or greater than the first reference voltage VREF1 and less than the second reference voltage VREF2 so the DQE signal may be converted into 01(2) that is the digital data signal DO during the section of t2 to t3. The voltage V3 of the DQE signal at t4 is equal to or greater than the second reference voltage VREF2 and less than the third reference voltage VREF3 so the DQE signal may be converted into 10(2) that is the digital data signal DO during the section of t3 to t4. Hence, the first analog-to-digital converter ADC1 may output 00(2) as the first digital data DO1, and the second analog-to-digital converter ADC2 may output 10(2) as the second digital data DO2. The third analog-to-digital converter ADC3 may output 01(2) as the third digital data DO3, and the fourth analog-to-digital converter ADC4 may output 10(2) as the fourth digital data DO4. The other analog-to-digital converters ADC5 to ADC32 may output digital data DO5 to DO32 in a like way.

Referring back to FIG. 5, the Mueller-Mueller phase detector 530 may detect a sampling timing error of the digital data signal DO received from the time interleaved analog-to-digital converter (TI ADC) 520. The Mueller-Mueller phase detector 530 may receive the continuous digital data signal DO from the time interleaved analog-to-digital converter (TI ADC) 520, and may calculate differences between the respective data samples to detect the sampling timing error. The Mueller-Mueller phase detector 530 may transmit a sampling control signal (hereinafter, DX) that is a control signal for correcting the sampling timing error to the loop filter 540.

In some example embodiments, the Mueller-Mueller phase detector 530 may receive the digital data signal DO and may determine a phase delay or a phase lead of the digital data signal DO. In some example embodiments, Mueller-Mueller phase detector 530 may determine the phase delay or the phase lead of the digital data signal DO based on two digital or at least two data signals DO. For example, the Mueller-Mueller phase detector 530 may determine the phase delay or the phase lead of the digital data signal DO based on the digital data signal DO converted at adjacent or neighboring timings. The Mueller-Mueller phase detector 530 may detect the sampling timing error based on the determination of the phase delay or the phase lead of the digital data signal DO.

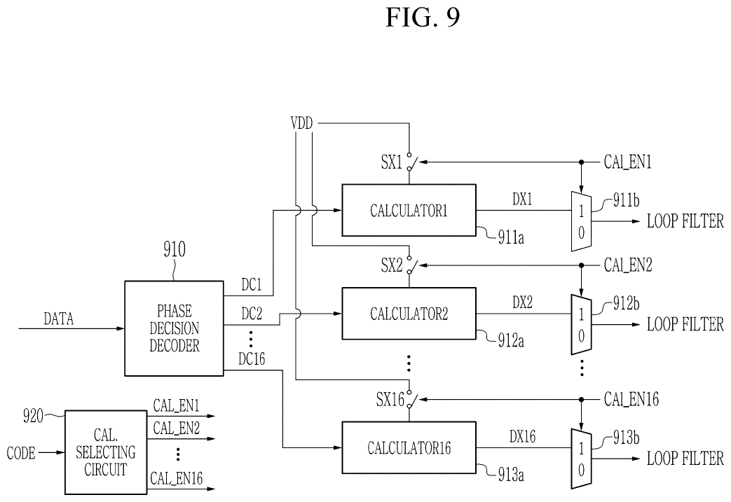

FIG. 9 shows a block diagram on a configuration of a Mueller-Mueller phase detector according to some example embodiments.

The phase determining decoder 910 may receive the digital data signal DO from the time interleaved analog-to-digital converter (TI ADC) 520 of FIG. 5. The phase determining decoder 910 may generate transition information of the digital data signal DO and may determine whether the phase of the digital data signal DO is a lead or a delay based on the two digital data signals DO that are continuously input. The phase determining decoder 910 may select one of or at least one of operators 911a, 912a, . . . , 913a based on the transition information. The phase determining decoder 910 may output phase determining signals DC1, DC2, . . . , DC3 to the selected operators 911a, 912a, . . . , 913a. The phase determining signals DC1, DC2, . . . , DC3 may include values and phase information of the at least two digital data signals DO, and/or may be based on values and phase information of the at least two data signals DO.

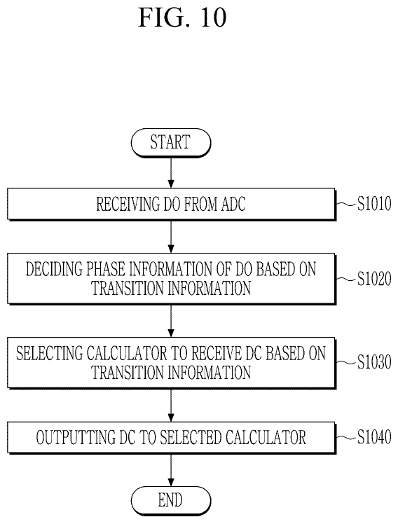

FIG. 10 shows a flowchart on an operation of a phase determining decoder according to some example embodiments.

At operation S1010, the phase determining decoder 910 of FIG. 9 may receive the digital data signal DO from the time interleaved analog-to-digital converter (TI ADC) 520 of FIG. 5. The phase determining decoder 910 may receive two digital data DO(N) and DO(N-1) that are continuously input.

At operation S1020, the phase determining decoder 910 may determine phase information of the digital data signal DO based on transition information of the digital data signal DO. The phase information may include information indicating whether the digital data signal DO is a phase lead or a phase delay for the clock signal CK. The transition information may include transition in which the digital data signal DO is changed to the digital data signal DO(N) from the digital data signal DO(N-1). The phase determining decoder 910 may obtain phase information and transition information of the digital data signal DO(N) based on the two digital data DO(N) and DO(N-1) that are continuously input.

Regarding the PAM4 signal, the digital data signals DO(N) and DO(N-1) respectively have a binary digital data signal DO so the number of transitions generated between the digital data signal DO(N) and the digital data signal DO(N-1) may be 16. The phase determining decoder 910 may obtain one of sixteen transition information based on the digital data DO(N) and DO(N-1). The phase determining decoder 910 may determine phase information of the digital data signal DO(N) based on the obtained transition information.

At operation S1030, the phase determining decoder 910 may select the operators 911a, 912a, . . . , 913a of FIG. 9 for receiving the phase determining signals DC1, DC2, . . . , DC3 of FIG. 9 based on transition information. For example, when the digital data signal DO(N-1) is 11(2), and the digital data signal DO(N) is 11(2) and equal to the digital data signal DO(N-1), the phase determining decoder 910 may select the first operator 911a. When the digital data signal DO(N-1) is 10(2) and the digital data signal DO(N) is 11(2), the phase determining decoder 910 may select the second operator 912a. When the digital data signal DO(N-1) is 00(2) and the digital data signal DO(N) is 00(2), the phase determining decoder 910 may select the sixteenth operator 913a. This is, however, an example.

Referring to FIG. 9, the operators 911a, 912a, . . . , and 913a for performing an operation may be determined based on transition information. For example, the operator 912a may perform the operation when the digital data signal DO(N) is 11(2) and is equal to the digital data signal DO(N-1). The operator 912a may perform the operation when the digital data signal DO(N-1) is 10(2) and the digital data signal DO(N) is 11(2). The operator 913a may perform the operation when the digital data signal DO(N) is 00(2) and is equal to the digital data signal DO(N-1). This is, however, an example.

The respective operators 911a, 912a, . . . , and 913a may perform the operation corresponding to one different transition from among the transitions generated between the digital data signal DO(N) and the digital data signal DO(N-1). The operators 911a, 912a, . . . , and 913a may receive a phase determining signal, and may generate a sampling control signal for controlling the timing of clock signals based on the phase determining signal.

Hence, interference among the operators 911a, 912a, . . . , and 913a may be minimized, and an operation processing rate may be increased.

The operators 911a, 912a, . . . , and 913a may receive driving voltages from individual voltage sources (VDD). Switches SX1, SX2, . . . , and SX16 may be connected between the operators 911a, 912a, . . . , and 913a and the voltage source (VDD). The switches SX1, SX2, . . . and SX16 may be or may include transistors; example embodiments are not limited thereto. The respective operators 911a, 912a, . . . , and 913a may receive the driving voltage from the voltage source (VDD) while the switches SX1, SX2, . . . , and SX16 are turned on.

The respective switches SX1, SX2, . . . , and SX16 may receive an operator selecting signal CAL_EN from an operator selecting circuit 920, and may be turned on or turned off based on the operator selecting signal CAL_EN. For example, the first switch SX1 may be turned on or turned off based on the first operator selecting signal CAL_EN1. The second switch SX2 may be turned on or turned off based on a second operator selecting signal CAL_EN2. The sixteenth switch SX16 may be turned on or turned off based on a sixteenth operator selecting signal CAL_EN3. According to some example embodiments, when the number of the operators 911a, 912a, . . . , and 913a receiving the driving voltage and driven is reduced from among the operators 911a, 912a, . . . , and 913a, an amount of power consumption generated by the Mueller-Mueller phase detector 530 of FIG. 5 may be reduced or improved upon.

The operator selecting circuit 920 may receive a code stored in the register 222 of FIG. 2, and may generate an operator selecting signal CAL_EN based on the code. For example, the operator selecting circuit 920 may receive 0001(2) that is a code for activating the first operator 911a, the second operator 912a, and the sixteenth operator 913a. The operator selecting circuit 920 may generate a first operator selecting signal CAL_EN1, a second operator selecting signal CAL_EN2, and a sixteenth operator selecting signal CAL_EN3 for turning on the switches SX1, SX2, and SX16 based on 0001(2) that is the received code.

The memory controller 120 of FIG. 1 may change the code stored in the mode register 222 by the MRW command. For example, the memory controller 120 may change 0001(2) stored in the code into 0010(2). The operator selecting circuit 920 may generate first to sixteenth operator selecting signals CAL_EN1 to CAL_EN3 for turning on the switches SX1 to SX16 based on 0010(2) that is the received code.

In some example embodiments, the operator selecting circuit 920 may directly receive the code from the memory controller 120. The operator selecting circuit 920 may generate the first to sixteenth operator selecting signals CAL_EN1 to CAL_EN3 based on the code received from the memory controller 120. For example, the operator selecting circuit 920 may receive 0001(2) that is the code for activating the first operator 911a, the second operator 912a, and the sixteenth operator 913a from the memory controller 120, and may generate the first operator selecting signal CAL_EN1, the second operator selecting signal CAL_EN2, and the sixteenth operator selecting signal CAL_EN3.

The operator selecting circuit 920 may transmit the first operator selecting signal CAL_EN1, the second operator selecting signal CAL_EN2, and the sixteenth operator selecting signal CAL_EN3 to the first multiplexer 911b, the second multiplexer 912b, and the sixteenth multiplexer 913b. The DX signals DX1 to DX16 that are operation values output by the operators 911a, 912a, . . . , and 913a may be input to the multiplexers 911b, 912b, . . . , and 913b of FIG. 9. The multiplexers 911b, 912b, . . . , and 913b may receive the operator selecting signal CAL_EN from the operator selecting circuit 920, and may determine whether to process the DX signals DX1 to DX16 based on the operator selecting signal CAL_EN. The multiplexers 911b, 912b, . . . , and 913b may receive a sampling control signal from the operator, and may selectively output the sampling control signal. The multiplexers 911b, 912b, . . . , and 913b may receive the DX signals DX1 to DX16 from the operators 911a, 912a, . . . , and 913a and may/may not transmit them to the loop filter 540 of FIG. 5 based on the operator selecting signal CAL_EN. The operator selecting signal CAL_EN received by the multiplexers 911b, 912b, . . . , and 913b may be the same as the operator selecting signal CAL_EN for selecting at least one of the operators 911a, 912a, . . . , 913a.

For example, the first multiplexer 911b, the second multiplexer 912b, and the third multiplexer 913b may transmit the DX1 signal, the DX2 signal, and the DX3 signal to the loop filter based on the first operator selecting signal CAL_EN1, the second operator selecting signal CAL_EN2, and the sixteenth operator selecting signal CAL_EN3 generated by the operator selecting circuit 920 by receiving 0001(2) that is the code for activating the first operator 911a, the second operator 912a, and the sixteenth operator 913a. The multiplexers excluding the first multiplexer 911b, second multiplexer 912b, and third multiplexer 913b may not transmit the received DX signals (DX3 to DX15) to the loop filter 540.

At operation S1040, the phase determining decoder 910 may output the phase determining signals DC1, DC2, ..., DC3 to the selected operators 911a, 912a, . . . , 913a. The phase determining decoder 910 may generate transition information of two digital data DO(N) and DO(N-1), and may determine phase information on the sampling timing of the two digital data DO(N) and DO(N-1). The phase determining decoder 910 may generate phase determining signals DC1, DC2, . . . , DC16 of FIG. 9 including phase information

The phase determining decoder 910 may output the phase determining signals DC1, DC2, . . . , DC3 to the operators 911a, 912a, . . . , 913a based on transition and phase information between the digital data signal DO(N) and the digital data signal DO(N-1).

For example, when the digital data signal DO is a phase lead for the clock signal CK, and the digital data signal DO is transitioned to 11(2) from 11(2), the phase determining decoder 910 may output the phase determining signal DC1 to the first operator 911a of FIG. 9. When the digital data signal DO is a phase lead for the clock signal CK, and the digital data signal DO is transitioned to 11(2) from 10(2), the phase determining decoder 910 may output the phase determining signal DC2 to the second operator 912a of FIG. 9. When the digital data signal DO is a phase lead for the clock signal CK, and the digital data signal DO is transitioned to 00(2) from 00(2), the phase determining decoder 910 may output the phase determining signal DC16 to the third operator 913a of FIG. 9. When the digital data signal DO is a phase delay for the clock signal CK and is transitioned to 00(2) from 00(2), the phase determining decoder 910 may output the phase determining signal DC1 to the first operator 911a. When the digital data signal DO is a phase delay for the clock signal CK and is transitioned to 11(2) from 10(2), the phase determining decoder 910 may output the phase determining signal DC2 to the second operator 912a. When the digital data signal DO is a phase delay for the clock signal CK and is transitioned to 11(2) from 11(2), the phase determining decoder 910 may output the phase determining signal DC16 to the third operator 913a. However, the method for the phase determining decoder 910 to output the phase determining signal DC1 to DC16 to the operator 912a, 912a, and 913a based on phase information and transition information.

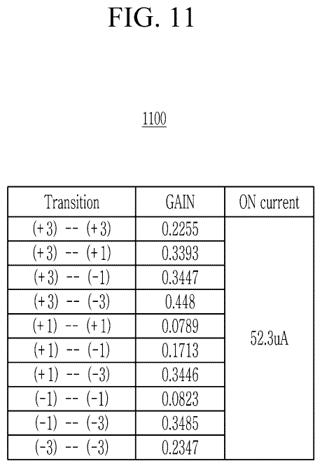

FIG. 11 shows a table on gains and current consumption generated by a Mueller-Mueller phase detector based on a transition of digital data.

Referring to FIG. 11, the gain may represent variability of a resultant value that is output according to a phase difference between the digital data signal DO and the clock signal CK input to the Mueller-Mueller phase detector 530 of FIG. 5. The variability of the resultant value may increase as the gain increases so that it may become easy to adjust the phase of the clock signal CK to accurately capture the digital data signal DO. A gain noise ratio (GNR) may be improved to remove a distortion phenomenon caused by noise of the digital data signal DO and the clock signal CK.

The gain may depend on a level of the voltage by which transition is generated from the digital data signal DO. For example, as a purely illustrative example without limitation, the gain of the Mueller-Mueller phase detector may be 0.2255(V/rad) regarding the transition to +3(V) from +3(V), the gain of the Mueller-Mueller phase detector may be 0.3393(V/rad) regarding the transition to +1(V) from +3(V), and the gain of the Mueller-Mueller phase detector may be 0.3447(V/rad) regarding the transition to −1(V) from +3(V). The gain of the Mueller-Mueller phase detector may be 0.448(V/rad) regarding the transition to −3(V) from +3(V), the gain of the Mueller-Mueller phase detector may be 0.0789(V/rad) regarding the transition to +1(V) from +1(V), and the gain of the Mueller-Mueller phase detector may be 0.01713(V/rad) regarding the transition to −1(V) from +1(V). The gain of the Mueller-Mueller phase detector may be 0.3446(V/rad) regarding the transition to −3(V) from +1(V), the gain of the Mueller-Mueller phase detector may be 0.0823(V/rad) regarding the transition to −1(V) from −1(V), the gain of the Mueller-Mueller phase detector may be 0.3485(V/rad) regarding the transition to −3(V) from −1(V), and the gain of the Mueller-Mueller phase detector may be 0.2347(V/rad) regarding the transition to −3(V) from −3(V).

When the Mueller-Mueller phase detector 530 detects the entire transitions generated by the digital data signal DO, the gain may increase and the amount of current consumption may also increase. The amounts of current consumption generated by the Mueller-Mueller phase detector 530 detecting the entire transitions may be 52.3 μA, respectively.

The Mueller-Mueller phase detector 530 may select at least one type of the transitions and may detect the selected transition from the digital data signal DO. The operators 911a, 912a, and 913a of FIG. 9 corresponding to the transition not selected by the Mueller-Mueller phase detector 530 may not receive the driving voltage from the voltage source VDD of FIG. 9 as the switches SX1, SX2, . . . , and SX16 are turned off. The operators 911a, 912a, and 913a are not driven so the amount of current consumption generated by the Mueller-Mueller phase detector 530 may be reduced. Hence, as the number of the transitions selected by the Mueller-Mueller phase detector 530 is reduced, the number of the driven operators 911a, 912a, and 913a is reduced so that the Mueller-Mueller phase detector 530 may be driven with low electric power.

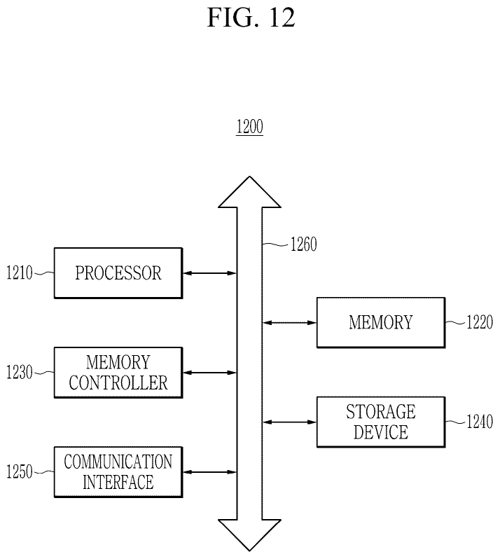

FIG. 12 shows a block diagram on a computer device according to some example embodiments.

Referring to FIG. 12, the computing device 1200 includes a processor 1210, a memory 1220, a memory controller 1230, a storage device 1240, a communication interface 1250 and a bus 1260. The computing device 1200 may further include other general-purpose constituent elements.

The processor 1210 controls some, or an overall operation of respective components of the computing device 1200. The processor 1210 may be implemented with at least one of various processing units such as one or more of a central processing unit (CPU), an application processor (AP), and a graphic processing unit (GPU).

The processor 1210 may obtain transition information based on two digital data DO, for example of FIG. 5, and may determine a phase delay or a phase lead of digital data signals DO. The processor 1210 may detect the sampling timing error of the digital data signal DO based on transition information and phase information.

The memory 1220 stores various types of data and instructions. The memory 1220 may be implemented with any one or more of the memory device described with reference to FIG. 1 to FIG. 11; example embodiments are not limited thereto. The memory controller 1230 controls transmission of data or instructions to/from the memory 1220. In some example embodiments, the memory controller 1230 may be provided as a chip that is separated from the processor 1210. In some example embodiments, the memory controller 1230 may be provided as an internal component of the processor 1210. In some example embodiments, the memory controller 1230 may correspond to the memory control 120 described with reference to FIG. 1.

The storage device 1240 non-temporarily and/or non-transiently stores programs and/or data. In some example embodiments, the storage device 1240 may be realized as a non-volatile memory. The communication interface 1250 supports wired/wireless Internet communication of the computing device 1200. The communication interface 1250 may support various types of communication schemes in addition to or in lieu of network communication. The bus 1260 provides a communication function among the components of the computing device 1200. The bus 1260 may include at least one type of bus according to a communication protocol among components.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While inventive concepts have been described in connection with what is presently considered to be some example embodiments, it is to be understood that the disclosure is not limited to the disclosed example embodiments, but, on the contrary, is intended to cover various modifications and equivalent arrangements included within the spirit and scope of the appended claims. Furthermore example embodiments are not necessarily mutually exclusive with one another. For example, some example embodiments may include one or more features described with reference to one or more figures, and may also include one or more other features described with reference to one or other figures.

What is claimed is:

1. A receiver comprising:
an analog front end configured to receive a data signal and to amplify the data signal to generate an amplified signal;
an analog-to-digital converter configured to sample the amplified signal based on clock signals, and to generate at least two digital data signals; and
a Mueller-Mueller phase detector configured to receive the digital data signals from the analog-to-digital converter, and to drive at least one operator from among a plurality of operators based on a transition between at least two continuously received digital data signals from among the digital data signals.

2. The receiver of claim 1, wherein
the Mueller-Mueller phase detector includes:
a phase determining decoder configured to generate transition information of the at least two digital data signals, determine phase information on the clock signals sampling the at least two digital data signals from among the clock signals, and output a phase determining signal including the phase information;
the at least one operator configured to receive the phase determining signal, and generate a sampling control signal for controlling timings of the clock signals based on the phase determining signal;
at least one switch configured to connect the at least one operator and a voltage source; and
at least one multiplexer configured to receive the sampling control signal from the at least one operator, and selectively output the sampling control signal.

3. The receiver of claim 2, wherein
the phase determining decoder is further configured to select a first operator from among the at least one operator based on the transition information and to output the phase determining signal to the first operator.

4. The receiver of claim 3, wherein
the phase determining signal further includes
the transition information, and
values based on the at least two digital data signals.

5. The receiver of claim 2, wherein
the Mueller-Mueller phase detector further includes an operator selecting circuit configured to output at least one switch control signal for turning on at least one switch from among the at least one switch based on a code.

6. The receiver of claim 5, wherein
at least one of the at least one multiplexer is further configured to output the sampling control signal based on the at least one switch control signal.

7. The receiver of claim 6, wherein
a first switch and a first multiplexer are configured to receive a same switch control signal,
the first switch from among the at least one switch, the first switch connected to a first operator from among the at least one operator, and
the first multiplexer from among the at least one multiplexer, the first multiplexer configured to receive the sampling control signal from the first operator.

8. A phase detecting device comprising:
at least one operator configured to correspond to transitions of at least two data sampling a multi-level signal at at least two adjacent sampling timings, and configured to operate a sampling control signal for adjusting the sampling timing at which the multi-level signal is sampled;
an operator selecting circuit configured to generate an operator selecting signal for selecting at least one of the at least one operator; and
at least one switch configured to transmit driving voltages to the at least one operator from a voltage source based on the operator selecting signal.

9. The phase detecting device of claim 8, further comprising
a phase determining decoder configured to generate transition information of the at least two data, determine phase information on at least two respective sampling timings of the at least two data, and output a phase determining signal including the phase information to one of the at least one operator.

10. The phase detecting device of claim 9, wherein
the phase determining decoder is further configured to select one of the at least one operator based on the transition information, and to output the phase determining signal to the selected operator.

11. The phase detecting device of claim 10, wherein
the phase determining signal further includes
the transition information, and
values based on at least two digital data signals.

12. The phase detecting device of claim 8, further comprising
a register configured to store codes,
wherein the operator selecting circuit is configured to generate the operator selecting signal based on the codes.

13. The phase detecting device of claim 8, wherein
the operator selecting circuit is further configured to receive a code and generate the operator selecting signal based on the code.

14. The phase detecting device of claim 8, further comprising
at least one multiplexer configured to selectively receive sampling control signals output by the at least one operator based on the operator selecting signal.

15. A phase detecting method comprising:
receiving at least two continuous digital data signals from a converter;
determining phase information based on transition information of the at least two digital data signals;
selecting an operator configured to receive a phase determining signal based on the transition information;
outputting the phase determining signal to the selected operator; and
transmitting a switch control signal to a switch connected between the selected operator and a voltage source.

16. The phase detecting method of claim 15, wherein
the determining of phase information based on transition information of the two digital data includes
generating transition information of the at least two digital data signals; and
determining phase information on clock signals by which the at least two digital data signals are sampled from among the clock signals.

17. The phase detecting method of claim 15, further comprising
turning on the switch based on the switch control signal;
applying a driving voltage to the operator from the voltage source; and
allowing the operator to generate a sampling control signal for controlling timings of clock signals based on the phase determining signal.

18. The phase detecting method of claim 17, wherein
the transmitting of a switch control signal to the switch connected between the selected operator and the voltage source includes
transmitting the switch control signal to a multiplexer connected to the operator.

19. The phase detecting method of claim 18, further comprising
allowing the multiplexer to receive the sampling control signal based on the switch control signal.

20. The phase detecting method of claim 15, wherein
the phase determining signal further includes
the transition information, and
values based on the two digital data signals.
